(19) United States
(12) Patent Application Publication
(10) Pub. No.: US 2019/0158064 A1
(43) Pub. Date: May 23, 2019

(54) RF FILTER WITH REDUCED INSERTION LOSS

(71) Applicant: SNAPTRACK, INC., San Diego, CA (US)

(72) Inventors: Werner RUILE, San Diego, CA (US); Sebastian BERTL, San Diego, CA (US); Markus HAUSER, San Diego, CA (US); Veit MEISTER, San Diego, CA (US)

(21) Appl. No.: 16/316,491

(22) PCT Filed: Jun. 26, 2017
(86) PCT No.: PCT/US2017/039270

§ 371 Date: Jan. 9, 2019

(30) Foreign Application Priority Data
Jul. 14, 2016 (DE) 10 2016 112 984.4

(51) Int. Cl. H03H 9/72; H03H 9/05; H03H 7/01; H03H 9/02

(52) U.S. Cl. CPC H03H 9/725; H03H 9/0576; H03H 9/02535; H03H 9/02007; H03H 7/0161

(57) ABSTRACT

The invention relates to an RF filter with reduced insertion loss. The filter (F) includes a first bandpass filter (BPF1) having a passband, a circuit unit (SE) having an undesired excitation at a critical frequency (fₛ) and a reflector (R) that reflects RF signals of this frequency before the circuit unit is undesirably excited and the power is lost as a result.

The invention relates to RF filters in which the insertion loss is reduced and a component having a lower power requirement due to a corresponding filter.

Filter circuits having a bandpass filter are known from the U.S. Pat. No. 7,583,936.

RF filters can be used in front-end circuits of mobile communication devices. Such devices are generally equipped with a power supply independent of a network. The higher the insertion loss of RF filters is, the higher the energy consumption. A lot of dissipated energy means not only a reduced operating time, but also leads to heating of the corresponding component, thus adversely affecting the temperature characteristics and output compatibility.

It is therefore an object of the invention to provide RF filters and components having such filters that reduce insertion loss.

Accordingly, it is also the object of the invention to provide RF filters and components having such filters, in which the electrical characteristics are less deteriorated by heat produced in an undesirable manner.

These objects are achieved by the RF filter according to the independent claim. Dependent claims specify advantageous embodiments.

The RF filter has an input port, a first bandpass filter, a circuit unit and a reflector. The input port is provided to receive RF signals from a circuit environment, for example transmission signals from a power reception amplifier or signals from an antenna. The first bandpass filter has a first transmission range, its passband. In the circuit unit, RF signals of a frequency fₛ cause undesired excitations. The reflector is provided to reflect RF signals of this frequency fₛ. The first bandpass filter and the switching unit are connected to the input port. The frequency fₛ is within the first passband, meaning in the transmission range of the first passband filter. The reflector is connected between the input port and the circuit unit.

The bandpass filter can be a conventional bandpass filter, such as a front-end circuit. The circuit unit of the RF filter is a part of the filter in which an undesired feedback, such as a resonance, would lead to loss of energy in the absence of further measures.

In typical RF filters—in particular when there is a plurality of bands to be covered—a bandpass filter and a circuit unit that dissipates RF energy in the passband of the bandpass filter can be connected to each other in such a manner that a part of the RF power is lost in the circuit unit and can no longer be transmitted from the bandpass filter at its output to an external circuit environment. The dissipation of energy in the circuit unit thus increases the insertion loss of the RF filter, even if the actual bandpass filter has an extremely low insertion loss.

The dissipated energy is not simply no longer there, it leads, instead, to a temperature change in the bandpass filter located nearby that could change their characteristic frequencies.

The reflector between the input port and the circuit unit reflects the RF signal that would otherwise be dissipated in the circuit unit, ideally to the first bandpass filter that can now transmit a maximum of RF power at its output port to the external circuit environment.

Circuit units that can be excited at the critical frequency fₛ are generally problematic. Although the circuit unit can be designed to be self-reflecting in a frequency range at the critical frequency fₛ, a pure reflection is, however, never possible because an excitation always imposes a positive real component of the input admittance that cannot be compensated.

It is possible, that the circuit unit is an RF filter.

Modern portable communication devices provide a plurality of functions and operate on a plurality of frequency bands. These devices comprise a plurality of RF filters having the corresponding characteristic passband and locking frequencies. In order to be able to build such devices as small as possible, it is useful to use electroacoustic filters. Such filters, for example SAW filters (SAW=Surface Acoustic Wave), BAW filters (BAW=Bulk Acoustic Wave) or GBAW filters (GBAW=Guided Bulk Acoustic Wave), have electrode structures that stimulate acoustic waves in a piezoelectric material and convert between RF signals and acoustic waves. Ideally, only the intended main modes are capable of propagating in such electroacoustic filters. Also, unwanted modes, such as plate modes or undesired volume waves as well as other non-linearly generated signals and higher harmonics are often excitable in actual components and constitute an energy-loss channel. Even if RF filters are designed in such a manner that signals generated by unwanted effects at the output port demonstrate such a weak level that the necessary specifications are fulfilled, the operating life is reduced in an undesirable manner by this energy loss. This problem is gaining more and more importance because communication devices provide more and more functions and cover more and more frequency ranges. The continuing trend towards miniaturization also exacerbates the pressure from the increased thermal load because the power density increases.

The reflector is connected in series in front of this branching filter so that this partial filter provided for a specific frequency range now diverts less or no energy from another filter. RF power that is fed into the RF filter at the input port can to a large extent pass directly to the first passband filter. A portion of the power that falls on the reflector is also reflected to the bandpass filter without dissipating in the circuit unit.

It is therefore possible in particular for the first bandpass filter and/or the circuit unit to operate with acoustic waves. The first bandpass filter can thus be a BAW filter, a SAW filter or a GBAW filter. The circuit unit can also be a BAW filter, a SAW filter or a GBAW filter.

The reflector can also be a low-pass filter, a high-pass filter or a band-stop filter.

Especially if the circuit unit is itself an RF filter, the reflector may not reflect RF signals in the entire frequency range in which the filter operates. The reflector must therefore operate in a frequency-selective manner and reflect RF power of a frequency that is within the passband of the first the bandpass filter. However, the reflector also may not reflect any signals required by the circuit element.

It is possible for the reflector to operate using acoustic waves. Alternately or additionally, it is possible that the reflector comprises LC links. If the filter is a band-stop filter, it can comprise two or more electroacoustic resonators. An electroacoustic band-stop filter can, for example, be obtained if a serial resonator and a parallel resonator in their characteristic frequencies are tuned in such a way that the anti-resonance frequency of the serial filter essentially equals the resonance frequency of the parallel resonator.

High-pass, low-pass or band-stop filters whose transition width is significantly larger than the transition width of electroacoustic filters can be obtained using LC links (L: inductive element, C: capacitance element). If the first passband of the first bandpass filter and an additional passband or operational range of the circuit unit are located sufficiently far apart, filters from LC links can easily suffice.

The use of high-pass filters or low-pass filters are particularly suitable for cascading if the RF filter circuit includes a plurality of filters in parallel paths arranged according to the operating frequency of the filters.

The reflector can rotate the phase of the RF signals of the frequency fₛ in such a manner that the reflected signals constructively overlap the RF signals on the first bandpass filter and thus reduce the insertion loss of the RF filter.

The RF filter receives RF signals at the input port. A part of the RF power passes directly to the first bandpass filter. Another part of the power is reflected by the reflector and passes as secondary power to the first bandpass filter. Ideally, the primary signals and the secondary signals have the same phase position so that a maximum of RF power can be transmitted at the output of the first bandpass filter. For this purpose, the reflector can have elements of an all-pass filter, whose influence on the phase position is designed so that primary and secondary signals on the first bandpass filter correspond in their phase positions.

It is possible that the unwanted excitations in the circuit unit are excitations in the frequency f, excitations from intermodulation products in signals in the frequency fₛ, excitations from harmonics, excitations caused by non-linear effects, broad-band excitations or excitations caused by volume waves.

If the circuit unit is directly stimulated at the frequency fₛ, these signals would be weakened. If intermodulation products are generated, for example if signals of the frequency fₛ encounter RF signals of different frequencies and the circuit unit does not have a 100% linear behavior, interference signals are generated on frequencies that depend upon whole number multiples of the difference between the coincident signals. These then represent only one energy-loss channel, but their frequency range can correspond to actually desired frequencies and can accordingly disrupt the desired signal.

The principle outlined above for preventing energy loss is functional at excitations of narrow frequency ranges up to excitations of wide frequency ranges. Excitations from volume waves, for example, generally have a lower frequency band edge (volume wave onset) that is followed by a wider frequency range having interfering excitations that can be cut out relatively easily using a low-pass filter.

It also applies that the undesired excitations are more likely to be at higher frequencies, which is why the use of a low-pass filter (or by cascading the use of a plurality of low-pass filters) is preferred.

The reflector prevents not only the reduction of insertion loss, but also improves the electrical characteristics of the RF filter, in particular the isolation.

As already mentioned, the multiple application of the principle described here can be used to increase the insertion loss. For this purpose, the RF filter can comprise two or more cascaded base units, each having a reflector and a circuit unit. In particular, it is possible for each circuit unit, which, in the absence of additional measures, would remove RF power from the signal path in an undesired manner, to have an associated reflector that cuts precisely this circuit unit off from the signals of the critical frequency. It is also possible for the RF filter to have a signal path. The reflector is switched in the signal path. Furthermore, the signal path has additional reflectors or connects in series to the reflector in the signal path. These reflectors can either be all high-pass filters or all low-pass filters. The reflectors are cascaded in the signal path and sorted according to their cut-off frequencies.

Seen in the direction of the signal, a corresponding circuit unit, for example a corresponding RF filter in a parallel path, can branch from the signal branch in the signal path downstream from each reflector.

When using high-pass filters as reflectors, the following applies: The RF filters arranged in the branching parallel paths are arranged in descending order according to their operating frequency, as seen in the signal direction. The bandpass filter located closest to the input port operates at the highest frequency. Seen in the direction of the signal, a following branching bandpass filter operates at a narrower frequency and has an excitation at the operating frequency of the previous bandpass filter. The low-pass filter arranged in between allows RF signals of the operating frequency of the second bandpass filter to pass but reflects signals of the operating frequency of the previously branching bandpass filter, which would otherwise lead to an excitation at the operating frequency of the first filter. If high-pass filters are used, the reverse order applies to the sorting of the bandpass filters based on their operating frequencies.

Somewhat more generally formulated, the use of reflectors operating in a broad-band manner allows for cascading if the order of reflectors and circuit units given above is maintained. This differentiates the current RF filter from filters according to U.S. Pat. No. 7,583,936.

Because the first bandpass filter itself preferably operates using acoustic waves and possibly exhibits non-linear effects, the first bandpass filter can itself have an undesired excitation at a frequency f. The first bandpass filter can therefore be connected in a parallel path and an additional circuit element can be connected parallel to the first bandpass filter. The additional circuit element can, upon application of a corresponding RF signal, create a signal in transmission that is opposed to the undesired excitation of the first bandpass filter. The output of the first bandpass filter and the output of the additional circuit element can be connected together so that the opposing signal created and the undesired signal in the first bandpass filter interfere destructively.

Although a 100% reflection cannot be compensated during an excitation because of the positive actual portion of the input admittance, this arrangement makes it possible in transmission. A corresponding arrangement for negative interference can therefore, in principle, operate very efficiently.

In the case of a first bandpass filter in a parallel path that itself has undesired excitations at a frequency f, it is possible to connect an additional filter having a stop band around the frequency f in series after the first bandpass filter. Such a filter connected in series can be a low-pass filter or a high-pass filter that lets signals on the operating frequency of the first bandpass filter pass but diverts or dissipates the generated interference signals. In particular if these are signals of a frequency range that should not be further transmitted to an external circuit unit, the insertion loss is not thereby reduced.

The RF filter can be used and connected in a filter component. A corresponding filter component can also be part of a front-end circuit.

The RF filter and its underlying functional principles, as well as any possible embodiments are described in detail in reference to the schematic figures described below.

Shown are:

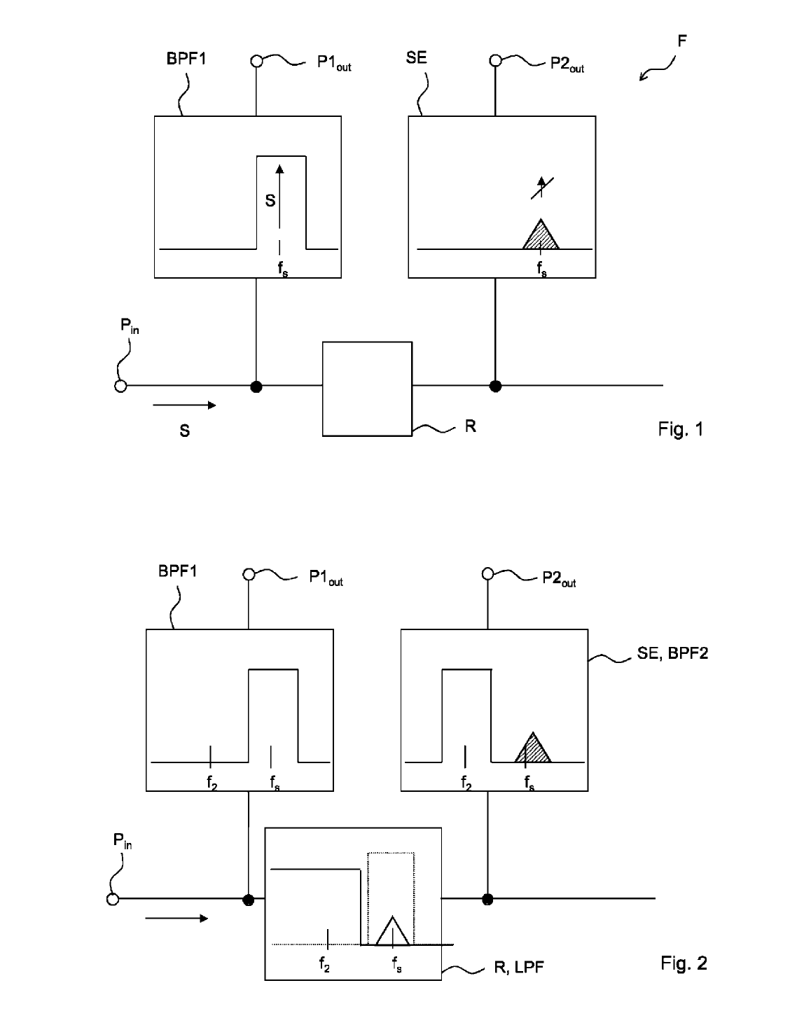

FIG. 1: the basic scheme of the RF filter F,

FIG. 2: one possible form having filters,

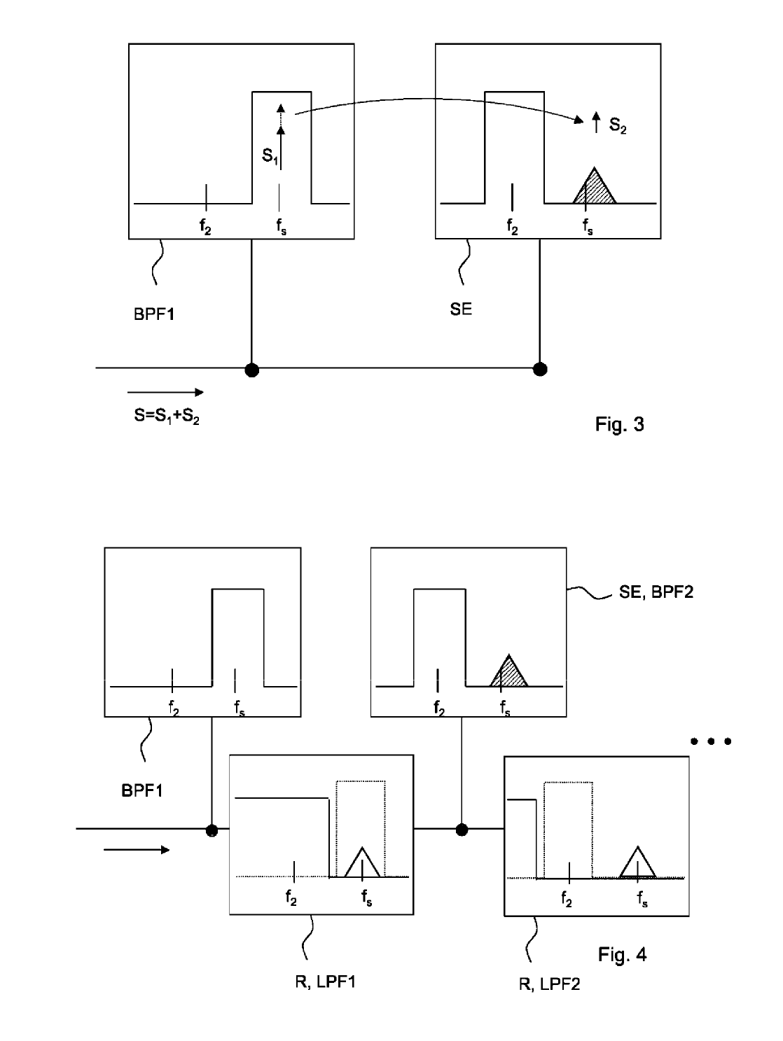

FIG. 3: an illustration of the problem that leads to a higher insertion loss in conventional circuits,

FIG. 4: a transfer of the principle to circuits having a plurality of parallel-connected filters,

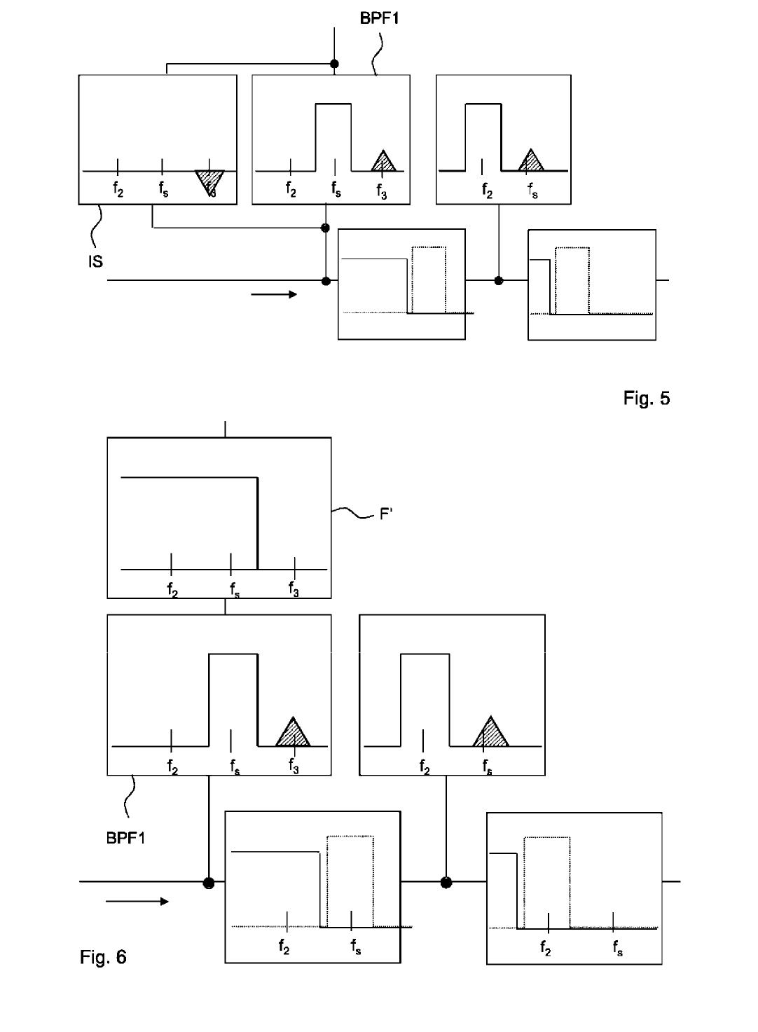

FIG. 5: the additional possibility for reducing interference modes using a parallel circuit element,

FIG. 6: the possibility for reducing additional interference modes using an additional, serial circuit element.

FIG. 1 shows the fundamental operating mode for improving the insertion loss of a RF filter F. Filter F has an input port Pᵢₙ, into which is supplied a signal S having a specific intensity. A first bandpass filter BPF1 is connected to input port Pᵢₙ. The first bandpass filter BPF1 has a passband around a frequency fₛ. A circuit unit SE is connected in parallel to first bandpass filter BPF1 and to input port Pᵢₙ. Circuit unit SE can be excited at frequency fₛ (symbolized by the hatched triangle). Signal S supplied to input port Pᵢₙ reaches first bandpass filter BPF1. Full power can be output at output port P1ₒᵤₜ. The reflector R is connected between first bandpass filter BRF1 and circuit unit SE and reflects corresponding RF power of frequency fₛ back to first bandpass filter BPF1.

FIG. 2 shows a possible form of the filter in which reflector R is designed as a low-pass filter LP. Circuit unit SE is designed as a bandpass filter, in this case next to first bandpass filter BPF1 as second bandpass filter BPF2. Signals of critical frequency fₛ are output via first bandpass filter BPF1 at its output P1ₒᵤₜ. Signals of the frequency f₂, the operating frequency of second bandpass filter BPF2, are transmitted practically unaltered by low-pass filter LP and are made available at output port P2ₒᵤₜ of second bandpass filter BPF2. Reflector R or low-pass filter LP reflects signals that are dissipated in bandpass filter BPF2 or converted into interference signals but admits signals of the operating frequency of second bandpass filter BPF2 unchanged.

Depending upon the frequency setting of the operating frequency of the bandpass filter and the situation of the interfering excitation and depending upon the order of the two bandpass filters as seen from input port Pᵢₙ, either a low-pass filter or a high-pass filter is advantageous as a reflector. Alternatively a band-stop or a band-pass filter can also be used as a reflector.

FIG. 3 illustrates the problem of conventional RF filters. The intensity of input signal S splits into two parts. The majority S₁ passes through the first bandpass filter. A second part S₂, however, passes into the circuit unit and effects an excitation at critical frequency fₛ. This intensity is lost. The insertion loss for signals around critical frequency fₛ of the RF filter increases in an undesired manner.

FIG. 4 shows an application of the principle of reflection on an RF filter having more than one bandpass filter and one circuit element, symbolized by the three dots. For each circuit having possible critical excitation or dissipation, a reflector can be provided, represented in FIG. 4 as low-pass filters LPF1, LPF2. The order of the parallel paths having bandpass filters or circuit units must be selected to correspond to the situation of the operating frequencies and the critical frequency. Low-pass filters or high-pass filters cascaded in the signal path and sorted according to their crossover frequency can then be used as reflectors.

FIG. 5 shows an inverter circuit IS that can be connected in parallel to a bandpass filter or a circuit unit. If first bandpass filter BPF1 (or another corresponding element in a parallel path) itself has a critical frequency in which interference signals are excited or desired signals dissipated, an inverter circuit IS can be provided that creates an output signal on this critical frequency that is equal to the inverted interference signal. This leads to an overlap on the interconnected outputs of the corresponding partial circuits, so that the negative impact of first band-pass filter BPF1 is nullified.

FIG. 6 shows an additional or alternate possibility for eliminating interference signals. If the power of the interference signal is not otherwise necessary, a simple low-pass filter F′ (or a high-pass filter or a stop-band filter, as appropriate) can be connected in series after bandpass filter BPF1.

The RF filter is not limited to the illustrated exemplary embodiments and described embodiments. The filter can include additional circuit elements, impedance matching circuits, circuit units for correcting phase responses, additional bandpass filters and the like.

### LIST OF REFERENCE NUMERALS

BPF1: First bandpass filter

BPF2: Second bandpass filter

F: RF filter

F′: Filter connected in series for interference signal suppression

f₂: Operating frequency in the passband of the second bandpass filter BPF2

f₃: Frequency of a possible interference in the first bandpass filter

fₛ: Critical frequency of the undesired excitation

HP: High-pass filter

IS: Inverter circuit

LP: Low-pass filter

LPF1: First low-pass filter

LPF2: Second low-pass filter

P1ₒᵤₜ: Output port of the first bandpass filter

P2ₒᵤₜ: Output port of the circuit unit

Pᵢₙ: Input port of the RF filter

R: Reflector

S: Intensity of the RF signal

S1: First intensity

S2: Intensity that, absent the reflector, would be dissipated through the undesired excitation in the circuit unit

SE: Circuit unit

1. An RF filter (F) having reduced insertion loss, comprising
an input port (Pᵢₙ),
a first bandpass filter (BPF1) having a first passband,
a circuit unit (SE), in which RF signals of the frequency fₛ cause undesired excitations,
a reflector (R) that reflects RF signals of a frequency fₛ,
wherein
the first bandpass filter (BPF1) and the circuit unit (SE) are connected to the input port (Pᵢₙ),
the frequency fₛ is within a first passband and
the reflector (R) is connected between the input port (Pᵢₙ) and the circuit unit (SE).

2. The RF filter according to the preceding claim, wherein the circuit unit is an RF filter.

3. The RF filter according to either of the preceding claims, wherein the bandpass filter (BPF1) and/or the circuit unit (SE) operate using acoustic waves.

4. The RF filter according to any of the preceding claims, wherein the reflector (R) is a low-pass filter, a high-pass filter or a band-stop filter.

5. The RF filter according to any of the preceding claims, wherein the reflector (R) operates using acoustic waves or includes LC links.

6. The RF filter according to any of the preceding claims, wherein the reflector (R) rotates the phase of the RF signal of the frequency fₛ in such a manner that the reflected signals constructively overlap the RF signals on the first bandpass filter (BPF1) and reduce the insertion loss of the RF filter (F).

7. The RF filter according to any of the preceding claims, wherein the undesired excitations are
excitations of frequency fₛ,
excitations of intermodulation products from signals of the frequency fₛ,
excitations from harmonics,
excitations caused by non-linear effects,
broad-band excitations or
excitations caused by volume waves.

8. The RF filter according to any of the preceding claims, additionally comprising two or more cascaded base units, each having a reflector (R) and a circuit unit (SE).

9. The RF filter according to any of the preceding claims,
in which the reflector (R) is connected in a signal path,
in which the RF filter (F) includes additional reflectors (R) that are connected in series to the reflector (R) in the signal path,
in which these reflectors (R) are either all high-pass filters or all low-pass filters,
in which the reflectors (R), sorted in the signal path according to their cut-off frequencies, are cascades in series.

10. The RF filter according to any of the preceding claims,
in which the first bandpass filter (BPF1) is connected in a parallel path and itself has undesired excitations at a frequency f,
in which an additional switching segment (IS) is connected in parallel to the first bandpass filter (BPF1) and in transmission creates an opposing signal to an undesired excitation of the first bandpass filter (BPF1) that destructively interferes with the undesired signal of the first bandpass filter (BPF1).

11. The RF filter according to any of the preceding claims,
in which the first bandpass filter (BPF1) is connected in a parallel path and itself has undesired excitations at a frequency f,
in which an additional filter having a stop band around the frequency f is connected in series after the first bandpass filter (BPF1).

12. A filter component having an RF filter according to any of the preceding claims.

13. A front-end circuit having a filter component according to the previous claim.
